(19) United States
(12) Patent Application Publication
(10) Pub. No.: US 2021/0385961 A1
(43) Pub. Date: Dec. 9, 2021

(54) FIXING ASSEMBLY FOR DATA STORAGE DEVICE

(71) Applicants: Inventec (Pudong) Technology Corporation, Shanghai (CN); INVENTEC CORPORATION, Taipei (TW)

(72) Inventor: Han-Chih HSIEH, Taipei (TW)

(21) Appl. No.: 17/019,699

(22) Filed: Sep. 14, 2020

(30) Foreign Application Priority Data
Jun. 9, 2020 (CN) 202010517964.9

(51) Int. Cl. H05K 7/14

(52) U.S. Cl. CPC H05K 7/1418; H05K 7/1407; H05K 7/1431

(57) ABSTRACT

The disclosure provides a fixing assembly including a cage, a circuit board, a mount seat, and a fastener. The cage has an accommodation space, a first opening, a second opening, and a mount portion. The accommodation space is configured to accommodate a data storage device. The first opening and the second opening are connected to the accommodation space, and the mount portion protrudes from the first opening. The circuit board is fixed on the mount portion. The circuit board has a first electrical connector and a second electrical connector located at opposite surfaces of the circuit board and having different interfaces, and the first electrical connector is configured for an insertion of the data storage device. The mount seat has a first guiding portion, the cage has a second guiding portion mating with the first guiding portion. The fastener is configured to fix the cage to the mount seat.

### CROSS-REFERENCE TO RELATED APPLICATIONS

This non-provisional application claims priority under 35 U.S.C. § 119(a) on Patent Application No(s). 202010517964.9 filed in China on Jun. 9, 2020, the entire contents of which are hereby incorporated by reference.

### BACKGROUND OF THE INVENTION

### Technical Field of the Invention

The disclosure relates to a fixing assembly, more particularly to a fixing assembly having a cage and a circuit board fixed to each other.

### Description of the Related Art

In general, a server may equip with multiple data storage devices to store data, programs or files. In general, the data storage device is a 2.5-inch or 3.5-inch hard disk drive (i.e., HDD). In order to read and write data fast, a solid-state drive was developed, but the solid-state drive had a higher price at that time, therefore it was not commonly used.

As technology progresses, the present price of the solid-state drive has been decreased to satisfy the demand of a user. As such, the user gradually adopts the solid-state drive in the server. However, the casing of the server is merely suitable for the 2.5-inch or 3.5-inch HDD, therefore it requires to provide another casing in order to accommodate the solid-state drive. On the other hand, users may have different requirements, some would like to adopt the 2.5-inch or 3.5-inch in the server, while another would like to adopt the solid-state drive having faster speed. Therefore, the manufacturer may have to design different casings for different kinds of data storage devices, which may increase the cost spending on manufacturing the server.

### SUMMARY OF THE INVENTION

The disclosure provides a fixing assembly, which is capable of allowing the solid-state drive to be compatible to the casing which is exclusive for the hard disk drive.

One embodiment of the disclosure provides a fixing assembly. The fixing assembly is configured to accommodate a data storage device and configured to be mounted on a casing. The fixing assembly includes a cage, a circuit board, a mount seat, and a fastener. The cage has an accommodation space, a first opening, a second opening, and a mount portion. The accommodation space is configured to accommodate the data storage device. The first opening and the second opening are respectively connected to two opposite sides of the accommodation space, and the mount portion protrudes from the first opening. The circuit board is fixed on the mount portion of the cage. The circuit board has a first electrical connector and a second electrical connector located at two opposite surfaces of the circuit board. The first electrical connector and the second electrical connector have different interfaces, and the first electrical connector is configured for an insertion of the data storage device. The mount seat is configured to be fixed on the casing. The mount seat has a first guiding portion, the cage has a second guiding portion. The first guiding portion and the second guiding portion mates with each other so as to guide a movement of the cage with respect to the mount seat. The fastener is configured to fix the cage to the mount seat.

According to the fixing assembly as discussed above, since the cage is installed on the casing via the fastener and the mount seat, and the circuit board is fixed on the cage and has the first electrical connectors and the second electrical connectors having different interfaces, the data storage device (e.g., solid-state drive) can be installed on the casing via the cage, and the data storage device can be electrically connected to another electronic component (e.g., the motherboard) via the first electrical connector and the second electrical connector of the circuit board. Therefore, the cage and the circuit board fixed on the cage can achieve the installation of the data storage device on the casing which is not designed for the data storage device. Accordingly, there is no need to design another casing for accommodating the data storage device, thereby saving the cost in manufacturing the server.

### BRIEF DESCRIPTION OF THE DRAWINGS

The present disclosure will become more fully understood from the detailed description given hereinbelow and the accompanying drawings which are given by way of illustration only and thus are not limitative to the present disclosure and wherein:

FIG. 1 is a perspective view of a fixing assembly according to one embodiment of the disclosure;

FIG. 2 is an exploded view of the fixing assembly in FIG. 1;

FIG. 3 is an exploded view of a cage of the fixing assembly in FIG. 1;

FIG. 4 is a cross-sectional view of the fixing assembly in FIG. 1;

FIG. 5 is another perspective view of the fixing assembly in FIG. 1; and

FIG. 6 is a perspective view of the fixing assembly in FIG. 5 when the cage is moved with respect to the mount seat.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

In addition, the following embodiments are disclosed by the figures, and some practical details are described in the following paragraphs, but the present disclosure is not limited thereto. Furthermore, for the purpose of illustration, some of the structures and components in the figures are simplified, and wires, reference lines or buses are omitted in some of the figures.

Moreover, the terms used in the present disclosure, such as technical and scientific terms, have its own meanings and can be comprehended by those skilled in the art, unless the terms are additionally defined in the present disclosure. That is, the terms used in the following paragraphs should be read on the meaning commonly used in the related fields and will not be overly explained, unless the terms have a specific meaning in the present disclosure.

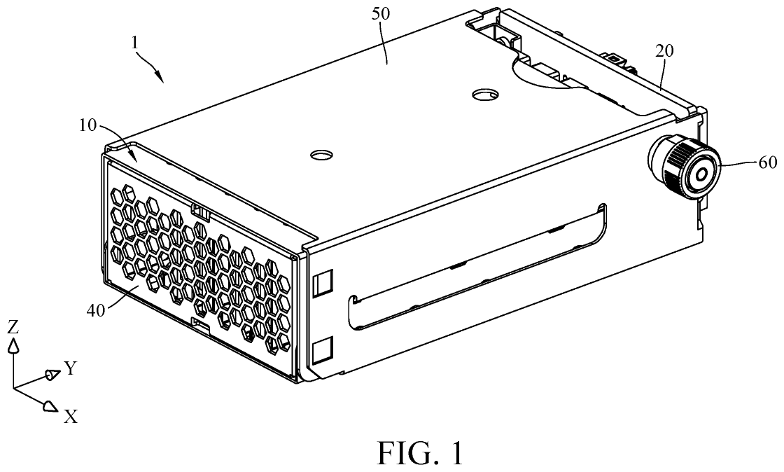

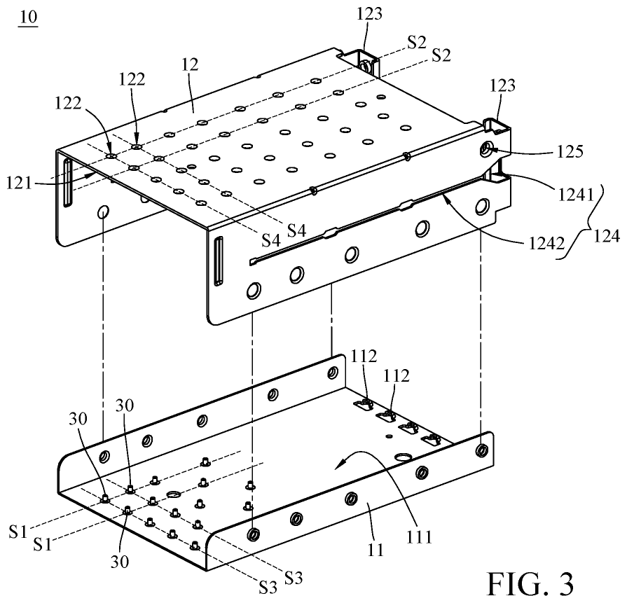

Referring to FIGS. 1 to 4, there are shown a perspective view of a fixing assembly 1 according to one embodiment of the disclosure, an exploded view of the fixing assembly 1 in FIG. 1, an exploded view of a cage 10 of the fixing assembly 1 in FIG. 1, and a cross-sectional view of the fixing assembly 1 in FIG. 1.

In this embodiment, the fixing assembly 1 is configured to accommodate at least one data storage device 2 and can be mounted on, for example, a server casing (not shown). The data storage device 2 is, for example, a solid-state drive. The fixing assembly 1 includes a cage 10 and a circuit board 20. In addition, in this or another embodiment, the fixing assembly 1 may further include a plurality of positioning components 30.

The cage 10 includes a bottom part 11 and a top part 12. The bottom part 11 and the top part 12 are U-shaped plates. Two opposite sides of the bottom part 11 and two opposite sides of the top part 12 are, for example, riveted with each other. The bottom part 11 and the top part 12 together form an accommodation space 13, a first opening 14 and a second opening 15. The first opening 14 and the second opening 15 are connected to two opposite sides of the accommodation space 13.

In this embodiment, the bottom parts 11 of the cage 10 has an inner bottom surface 111 facing the accommodation space 13, and the top part 12 of the cage 10 has an inner top surface 121 facing the inner bottom surface 111. The positioning component 30 is disposed on the inner bottom surface 111 of the bottom part 11, and the positioning components 30 are arranged along a plurality of first straight lines S1 spaced apart from each other. The first straight lines S1 extend from the second opening 15 of the cage 10 toward the first opening 14 and are parallel to each other. The top part 12 of the cage 10 further has a plurality of positioning structures 122. The positioning structures 122 are, for example, formed by a stamping process. The positioning structures 122 are arranged along a plurality of second straight lines S2 spaced apart from each other, and the second straight lines S2 extend from the second opening 15 of the cage 10 toward the first opening 14 and are parallel to each other. In this embodiment, the second straight lines S2 are parallel to and respectively correspond to the first straight lines S1, such that the positioning components 30 located on adjacent two of the first straight lines S1 and the positioning structures 122 located on adjacent two of the second straight lines S2, respectively corresponding to the two first straight lines S1, together form an insertion hole 16. The insertion hole 16 is configured for an insertion of the data storage device 2, and the positioning components 30 and the positioning structures 122 can guide the insertion of the data storage device 2 so as to prevent the data storage device 2 from being inserted improperly.

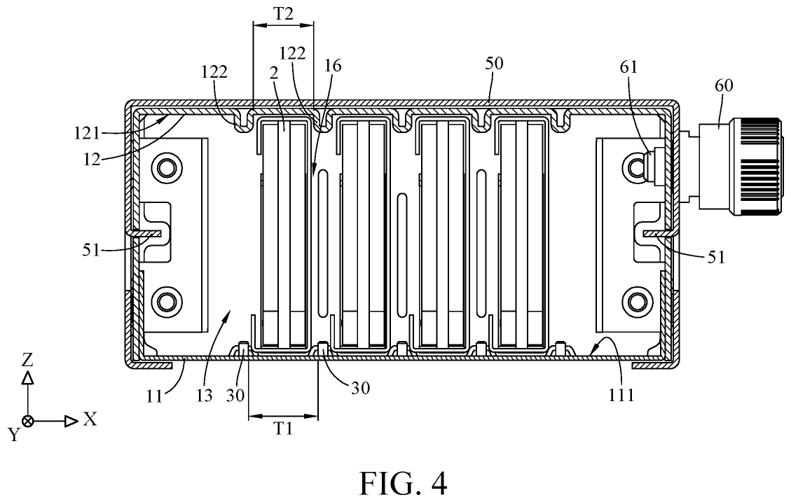

In this embodiment, the positioning components 30 are also arranged along a plurality of third straight lines S3 spaced apart from each other, and the third straight lines S3 are perpendicular to the first straight lines S1. In addition, the positioning structures 122 are also arranged along a plurality of fourth straight lines S4 spaced apart from each other, and the fourth straight lines S4 are perpendicular to the second straight lines S2. A distance T1 between adjacent two of the positioning components 30 located on one of the third straight lines S3 is larger than a distance T2 between adjacent two of the positioning structures 122 located on one of the fourth straight lines S4. As shown in FIG. 4, the lower portion of the insertion hole 16 is wider than the upper portion of the insertion hole 16, which ensures and facilitates the insertion of the data storage device 2 into the insertion hole 16.

In this embodiment, the top part 12 of the cage 10 further has two mount portions 123 opposite to each other. The two mount portions 123 protrudes from the first opening 14. The circuit board 20 is fixed to the mount portions 123 via, for example, screws. In the invention, the quantity of the mount portions 123 is not restricted in two; in some other embodiments, the top part of the cage may have only one mount portion 123.

The circuit board 20 has a plurality of first electrical connectors 21 and a plurality of second electrical connectors 22. The first electrical connectors 21 and the second electrical connectors 22 are respectively located at two opposite surfaces of the circuit board 20. The first electrical connectors 21 and the second electrical connectors 22 have different interfaces. Each of the first electrical connectors 21 is configured for the insertion of the data storage device 2, and each of the second electrical connectors 22 is configured to be electrically connected to a motherboard (not shown) on a server via, for example, a cable (not shown).

In the invention, the quantities of the first electrical connectors 21 and the second electrical connectors 22 are not restricted; in some other embodiment, the circuit board may merely have one first electrical connector and one second electrical connector.

In addition, the bottom part 11 of the cage 10 may have a plurality of stoppers 112. The stoppers 112 protrude from the inner bottom surface 111 of the bottom part 11 and are respectively located at sides of the insertion holes 16 close to the first opening 14. The stopper 112 can stop the data storage device 2 from being overly inserted into the insertion hole 16.

In this embodiment, the fixing assembly 1 may further include a front plate 40. The front plate 40 is detachably mounted at the second opening 15 of the cage 10. The front plate 40 can prevent electromagnetic interference and limit the movement of the data storage device 2.

Furthermore, the fixing assembly 1 may further include a mount seat 50 and a fastener 60. The mount seat 50 is configured to be fixed on the casing. The mount seat 50 has a first guiding portion 53, and the top part 122 of the cage 10 has a second guiding portion 126. The first guiding portion 53 of the mount seat 50 and the second guiding portion 126 of the top part 122 of the cage 10 mates with each other so as to guide the movement of the cage 10 with respect to the mount seat 50. For example, the first guiding portion 53 of the mount seat 50 has flange portions 51 opposite to each other, and the second guiding portion 126 of the top part 12 of the cage 10 has two slots 124 opposite to each other. The flange portions 51 of the mount seat 50 are respectively and movably located in the slots 124. The slots 124 are the same in configuration and therefore only one of them will be introduced in hereinafter. The slot 124 has an entrance portion 1241 and an extension portion 1242 connected to each other. An end of the entrance portion 1241 away from the extension portion 1242 is connected to the first opening 14 and exposed to the outside, and the entrance portion 1241 tapers towards the second opening 15.

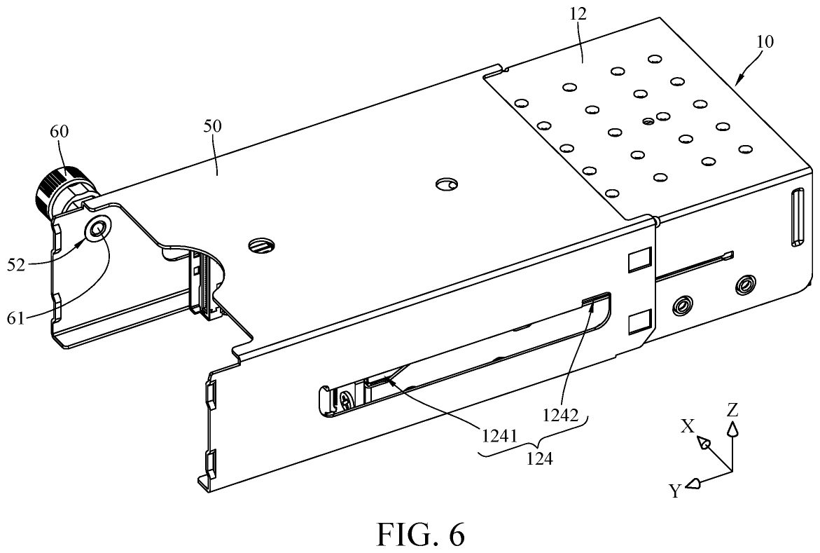

The mount seat 50 further has a through hole 52 (shown in FIG. 6), and the top part 12 has a through hole 125 located at a side of the top part 12. The through hole 52 of the mount seat 50 and the through hole 125 of the top part 12 corresponds to each other. The fastener 60 is, for example, a thumb screw or a spring bolt. The fastener 60 is disposed on the mount seat 50, and the fastener 60 has an insertion portion 61. The insertion portion 61 is movably disposed through the through holes 52 and 125 of the mount seat 50 and the top part 12 so as to fix the cage 10 to the mount seat 50.

In this embodiment, the casing is designed to accommodate 2.5-inch or 3.5-inch hard disk drives. Since the cage 10 is installed on the casing via the fastener 60 and the mount seat 50, and the circuit board 20 is fixed on the cage 10 and has the first electrical connectors 21 and the second electrical connectors 22 having different interfaces, the data storage device 2 (e.g., solid-state drive) can be installed on the casing via the cage 10, and the data storage device 2 can be electrically connected to another electronic component (e.g., the motherboard) via the first electrical connector 21 and the second electrical connector 22 of the circuit board 20. Therefore, the cage 10 and the circuit board 20 fixed on the cage 10 can achieve the installation of the data storage device 2 on the casing which was exclusive for the 2.5 inch or 3.5-inch hard disk drives. Accordingly, there is no need to design another casing for accommodating the data storage device 2, thereby saving the cost in manufacturing the server.

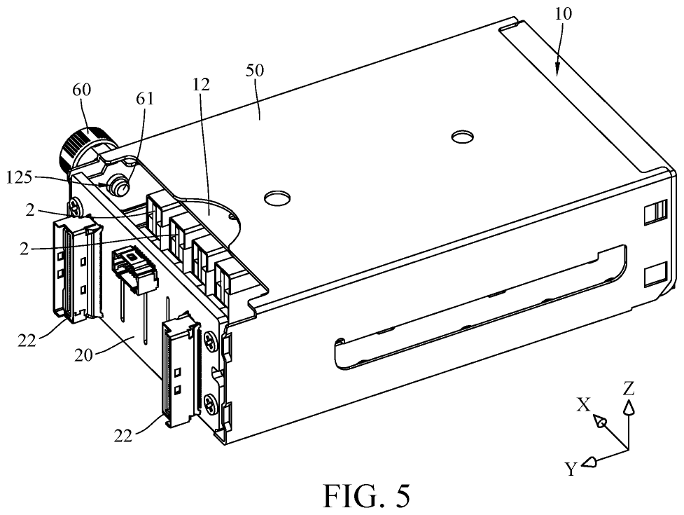

Then, referring FIGS. 5 and 6, there are shown another perspective view of the fixing assembly 1 in FIG. 1 and a perspective view of the fixing assembly 1 in FIG. 5 when the cage 0 is moved with respect to the mount seat 50. When the cage 10 is fixed to the mount seat 50, the fastener 60 can be pulled or rotated to make the insertion portion 61 move and detach from the through hole 125 of the top part 12, thus removing the fixation of the cage to the mount seat 50. At this moment, the cage 10 can be drawn out from the mount seat 50. Since the circuit board 20 is fixed to the cage 10, the circuit board 20 can be removed with the cage 10 while the cage 10 is being drawn out from the mount seat 50. Therefore, the removal of the cage 10 and the circuit board 20 can be finished in one time, and the 2.5-inch or 3.5-inch hard disk drive can be directly installed in the mount seat 50.

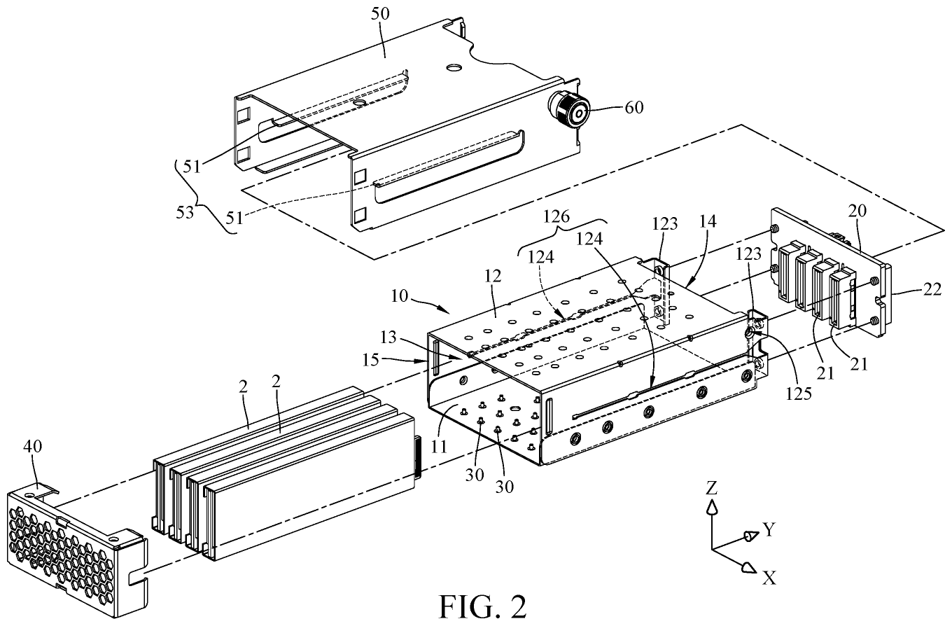

To mount the cage 10 into the mount seat 50, first step is to align the entrance portions 1241 of the slots 124 with the flange portions 51 (as shown in FIG. 2) of the mount seat 50, and then is to move the cage 10 with respect to the mount seat 50, such that the flange portions 51 will respectively enter into the extension portions 1242 of the slots 124 via the entrance portions 1241 of the slot 124. Then, the fastener 60 is rotated or pulled to move the insertion portion 61 away from the movement path of the cage 10. As the through hole 125 of the top part 12 of the cage 10 is aligned with the through hole 52 of the mount seat 50, the insertion portion 61 of the fastener 60 can be inserted into the through hole 125 of the top part 12 of the cage 10 for fixing the cage 10 to the mount seat 50.

Since the entrance portions 1241 of the slots 124 are in tapered shapes, the edges of the entrance portions 1241 can guide the flange portions 51 into the extension portions 1242 of the slots 124 during the installation of the cage 10 to the mount seat 50. Note that the slots 124 of the cage 10 and the flange portions 51 of the mount seat 50 are optional; in some other embodiments, the cage may have no slot, and the mount seat may have no flange portion.

According to the fixing assembly as discussed above, since the cage is installed on the casing via the fastener and the mount seat, and the circuit board is fixed on the cage and has the first electrical connectors and the second electrical connectors having different interfaces, the data storage device (e.g., solid-state drive) can be installed on the casing via the cage, and the data storage device can be electrically connected to another electronic component (e.g., the motherboard) via the first electrical connector and the second electrical connector of the circuit board. Therefore, the cage and the circuit board fixed on the cage can achieve the installation of the data storage device on the casing which is not designed for the data storage device. Accordingly, there is no need to design another casing for accommodating the data storage device, thereby saving the cost in manufacturing the server.

In addition, since the circuit board is fixed to the cage, the circuit board can be removed with the cage when the cage is drawn out from the mount seat. Therefore, the removal of the cage and the circuit board can be finished in one time, and the 2.5-inch or 3.5-inch hard disk drive can be directly installed in the mount seat.

In one embodiment of the disclosure, the server can be adopted in the artificial intelligence computing or the edge computing. In addition, the server may be a 5G server, a cloud server or a vehicle network server.

The embodiments were chosen and described in order to best explain the principles of the disclosure and its practical applications, to thereby enable others skilled in the art to best utilize the disclosure and various embodiments with various modifications as are suited to the particular use contemplated. It is intended that the scope of the disclosure be defined by the following claims and their equivalents.

What is claimed is:

1. A fixing assembly, configured to accommodate a data storage device and configured to be mounted on a casing, comprising:
a cage, having an accommodation space, a first opening, a second opening, and a mount portion, wherein the accommodation space is configured to accommodate the data storage device, the first opening and the second opening are respectively connected to two opposite sides of the accommodation space, and the mount portion protrudes from the first opening;
a circuit board, fixed on the mount portion of the cage, wherein the circuit board has a first electrical connector and a second electrical connector located at two opposite surfaces of the circuit board, the first electrical connector and the second electrical connector have different interfaces, and the first electrical connector is configured for an insertion of the data storage device;
a mount seat, configured to be fixed on the casing, wherein the mount seat has a first guiding portion, the cage has a second guiding portion, the first guiding portion and the second guiding portion mates with each other so as to guide a movement of the cage with respect to the mount seat; and
a fastener, configured to fix the cage to the mount seat.

2. The fixing assembly according to claim 1, further comprising a plurality of positioning components, wherein the cage has an inner bottom surface facing the accommodation space, the plurality of positioning components is disposed on the inner bottom surface of the cage, the plurality of positioning component are arranged along a plurality of first straight lines spaced apart from each other, the plurality of first straight lines extend from the second opening toward the first opening and are parallel to each other, and the plurality of positioning components located on adjacent two of the plurality of first straight lines together form an insertion hole.

3. The fixing assembly according to claim 2, wherein the cage has an inner top surface and a plurality of positioning structures, the inner top surface faces the inner bottom surface, the plurality of positioning structures are located at the inner top surface, the plurality of positioning structures are arranged along a plurality of second straight lines spaced apart from each other, the plurality of second straight lines extend from the second opening toward the first opening and are parallel to each other, the plurality of second straight lines are parallel to the plurality of first straight lines, and the plurality of positioning components located on adjacent two of the plurality of first straight lines and the plurality of positioning structures located on adjacent two of the plurality of second straight lines together form the insertion hole.

4. The fixing assembly according to claim 3, wherein the plurality of positioning components are arranged along a plurality of third straight lines spaced apart from each other, the plurality of third straight lines are perpendicular to the plurality of first straight lines, the plurality of positioning structures are arranged along a plurality of fourth straight lines spaced apart from each other, the plurality of fourth straight lines are perpendicular to the plurality of second straight lines, a distance between adjacent two of the plurality of the positioning component located on one of the plurality of third straight lines is larger than a distance between adjacent two of the plurality of positioning structures located on one of the plurality of fourth straight lines.

5. The fixing assembly according to claim 1, wherein the circuit board is fixed to the mount portion of the cage via screws.

6. The fixing assembly according to claim 1, wherein the cage has an inner bottom surface and a plurality of stoppers, the inner bottom surface faces the accommodation space, the plurality of stoppers protrude from the inner bottom surface, and the plurality of stoppers are configured to position the data storage device.

7. The fixing assembly according to claim 1, wherein the first guiding portion of the mount seat has two flange portions opposite to each other, the second guiding portion of the cage has two slots opposite to each, the two flange portions are respectively and movably located in the two slots.

8. The fixing assembly according to claim 7, wherein each of the two slots has an entrance portion and an extension portion connected to each other, ends of the entrance portions respectively away from the extension portions are connected to the first opening and expose to outside, and the entrance portions taper towards the second opening.

9. The fixing assembly according to claim 1, wherein the fastener has an insertion portion, and the insertion portion is disposed through a through hole of the mount seat and fixed to the cage.

10. The fixing assembly according to claim 1, further comprising a front plate, wherein the front plate is mounted at the second opening of the cage.
